(19) United States
(12) Patent Application Publication
(10) Pub. No.: US 2010/0224760 A1
(43) Pub. Date: Sep. 9, 2010

(54) IMAGING DEVICE AND METHOD FOR MANUFACTURING SAME, AND IMAGING METHOD

(75) Inventors: Yusaku KONNO, Kanagawa-ken (JP); Naotada Okada, Kanagawa-ken (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/716,758

(22) Filed: Mar. 3, 2010

(30) Foreign Application Priority Data
Mar. 4, 2009 (JP) 2009-050978

(51) Int. Cl. H01L 31/0232; H01L 27/146; H01L 31/18

(52) U.S. Cl. 250/208.1; 250/226; 250/216; 438/69; 257/E31.127

(57) ABSTRACT

An imaging device includes: an imaging lens; a light receiving element including a light receiving portion configured to sense light transmitted through the imaging lens; and a high refractive index member packed between the imaging lens and the light receiving element and having a higher refractive index than air.

### CROSS-REFERENCE TO RELATED APPLICATIONS

This application is based upon and claims the benefit of priority from the prior Japanese Patent Application No. 2009-050978, filed on Mar. 4, 2009; the entire contents of which are incorporated herein by reference.

### BACKGROUND OF THE INVENTION

1. Field of the Invention

This invention relates to an imaging device and a method for manufacturing the same, and an imaging method.

2. Description of the Related Art

Recently, with the increasing resolution of digital cameras and cell phone cameras, the arrayed light receiving element installed therein has been downscaled. However, the downscaling results in decreasing the pixel pitch spacing of the light receiving element. Hence, light incident on the lens cannot be efficiently guided into the light receiving portion such as a photoelectric conversion unit, causing the problem of unresolved pixels. In particular, when an imaging lens having a small F-number (small aperture) is used, light obliquely incident on the pixel increases, making this problem more manifest.

Conventionally, the arrayed light receiving element has been based on a focusing unit such as spherical microlenses. The purely spherical focusing unit has the effect of causing light perpendicularly incident on the arrayed light receiving element to be efficiently guided into the light receiving portion. However, it is less effective at efficiently guiding oblique incident light into the light receiving portion.

For instance, when light is incident on the arrayed light receiving element from a camera lens, the component of perpendicular incident light is intense in the center portion of the arrayed light receiving element, whereas the component of oblique incident light is intense in the peripheral portion of the arrayed light receiving element. The oblique incident light may impinge on a wiring and the like in the element and fail to reach the light receiving portion in the element, decreasing the light receiving sensitivity in the peripheral portion. Hence, in the two-dimensionally arrayed element, the light receiving sensitivity is high in the center portion, but low in the peripheral portion, causing a sensitivity difference (shading) therebetween. Furthermore, unless the oblique incident light is caused to reach the light receiving portion of the element using the focusing unit, it is incident on the light receiving portion of the adjacent pixel and may cause color mottling.

As a technique for guiding incident light toward the light receiving portion, for instance, JP-A 2007-141873 (Kokai) discloses a technique using a waveguide made of a material having a higher refractive index than the surroundings.

### SUMMARY OF THE INVENTION

According to an aspect of the invention, there is provided an imaging device including: an imaging lens; a light receiving element including a light receiving portion configured to sense light transmitted through the imaging lens; and a high refractive index member packed between the imaging lens and the light receiving element and having a higher refractive index than air.

According to another aspect of the invention, there is provided a method for manufacturing an imaging device, including: forming a light receiving element including a light receiving portion configured to sense light; forming a high refractive index member having a higher refractive index than air on an incident side of the light of the light receiving element so as to be in contact with the light receiving element; and forming an imaging lens on an incident side of the light of the high refractive index member so as to be in contact with the high refractive index member.

According to still another aspect of the invention, there is provided an imaging method including: transmitting light through an imaging lens; transmitting the light transmitted through the imaging lens through a high refractive index member being in contact with the imaging lens and having a higher refractive index than air; and being sensed the light transmitted through the high refractive index member by a light receiving element being in contact with the high refractive index member.

### BRIEF DESCRIPTION OF THE DRAWINGS

FIG. 1 is a schematic cross-sectional view illustrating an imaging device according to Example 1;

FIG. 2 is a schematic cross-sectional view enlarging a neighborhood (enclosed by the dotted line in FIG. 1) of a light receiving element of the imaging device;

FIG. 3 is a schematic perspective view showing an imaging device composed of an imaging lens and an arrayed light receiving element and a schematic view showing an enlarged portion of the arrayed light receiving element;

FIG. 4 is a schematic cross-sectional view enlarging a neighborhood of a light receiving element of an imaging device according to a comparative example contrasted with an embodiment;

FIGS. 5A and 5B are schematic views showing a traveling direction of light on the emitting side of the imaging lens;

FIG. 6 is a schematic cross-sectional view illustrating an imaging device according to Example 2;

FIG. 7 is a schematic cross-sectional view illustrating an imaging device according to Example 3; and

FIGS. 8A to 17C are schematic process cross-sectional views illustrating a method for manufacturing an imaging device according to the embodiment.

### DETAILED DESCRIPTION

An embodiment of the invention will now be described with reference to the drawings. In the drawings, like elements are labeled with like reference numerals, and the detailed description thereof is omitted as appropriate.

### EXAMPLE 1

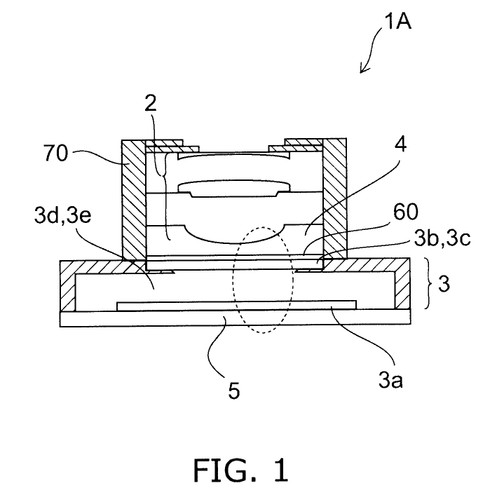

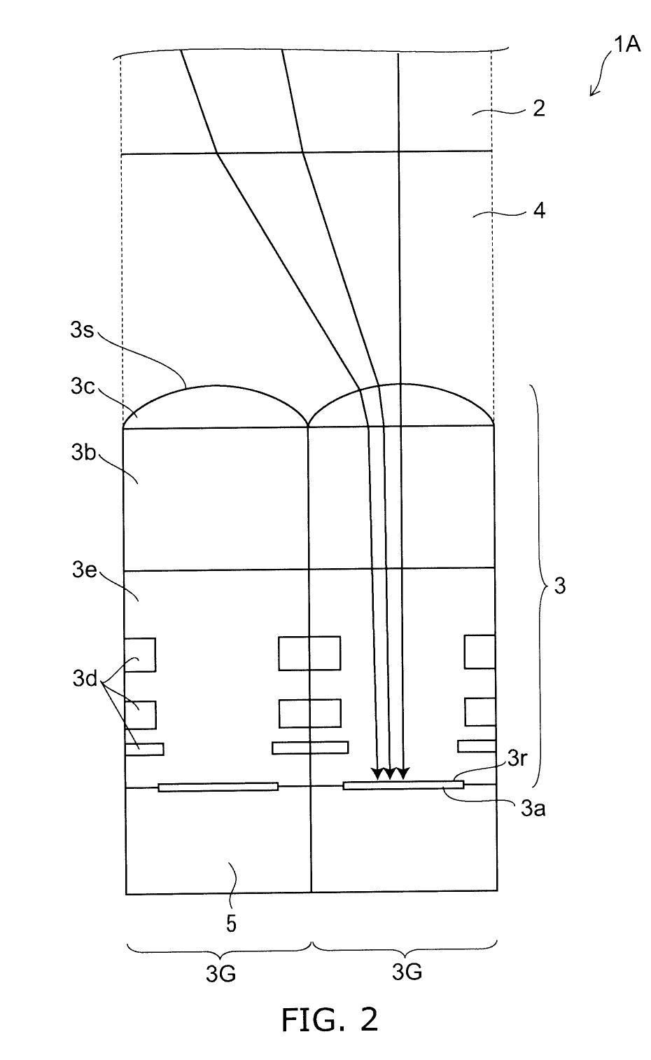

First, an example (Example 1) of an imaging device according to this embodiment is described with reference to FIGS. 1 and 2.

FIG. 1 is a schematic cross-sectional view illustrating an imaging device 1A according to Example 1.

FIG. 2 is a schematic cross-sectional view enlarging a neighborhood (enclosed by the dotted line in FIG. 1) of a light receiving element of the imaging device 1A. In FIG. 2, two pixels of an arrayed light receiving element 3 are shown. It is noted that an IR cut filter 60 shown in FIG. 1 and described later is not shown in FIG. 2.

As shown in FIGS. 1 and 2, the imaging device 1A includes an imaging lens 2, a light receiving element 3 including a light receiving portion 3a for sensing light transmitted through the imaging lens 2, and a high refractive index member 4 packed between the imaging lens 2 and the light receiving element 3 and having a higher refractive index than air.

The light receiving portion 3a can be a photoelectric conversion unit for converting light to an electrical signal, such as a photodiode illustratively made of Si.

The light receiving element 3 can include, on the light incident side, a color filter 3b for selectively transmitting light of red, green, blue and the like. The color filter 3b can be made of a material such as resin. In the following, the light incident side may be simply referred to as “incident side”, and the light emitting side may be simply referred to as “emitting side”.

The light receiving element 3 can include a plurality of pixels 3G, and the pixels 3G can include a focusing unit 3c for focusing light transmitted through the imaging lens 2. The focusing unit 3c is provided in the pixel 3G between the incident surface 3s and the major surface on which the light receiving portion 3a is provided, such as on the incident side of the color filter 3b. Here, the “major surface” is defined as a surface generally parallel to a light receiving surface 3r of the light receiving portion 3a.

The focusing unit 3c has a higher refractive index than the high refractive index member 4 and can be configured as having a convex surface on the incident side. The focusing unit 3c can be made of a material such as oxides and nitrides of metals and silicon, or resin, and suitably selected so as to have a higher refractive index than the high refractive index member 4.

The high refractive index member 4 has a higher refractive index than air (whose refractive index n at ordinary temperatures and pressures is approximately 1.0), and its material can illustratively be at least one of water (n=1.33), ethyl alcohol (n=1.35), benzene (n=1.5), resin-based material (such as polyethylene and polystyrene, n=1.5 to 1.6), and silicone (n≈1.4). Alternatively, its material can illustratively be a resin dispersed with metal oxide nano-sized particles (n≈1.7 to 1.9) containing at least one of zirconium (Zr), titanium (Ti), tin (Sn), cerium (Ce), tantalum (Ta), niobium (Nb), and zinc (Zn). Alternatively, its material can illustratively be a nitride (SiN, n=1.9). The high refractive index member 4 may have any one of vapor, liquid, and solid state at ordinary temperatures and pressures.

Wirings 3d may be provided between the color filter 3b and the major surface on which the light receiving portion 3a is disposed. The wiring 3d serves as a data transfer portion and can illustratively be made of Al or W. An insulating layer 3e is provided between the wirings. The insulating layer 3e can be made of a material such as SiO₂ or other oxides.

A substrate 5 illustratively made of Si is provided below the light receiving portion 3a. As shown in FIG. 1, a filter 60 for blocking infrared radiation (IR cut filter) may be provided on the incident side of the light receiving element 3. This suppresses hue change due to the effect of infrared radiation. Furthermore, the imaging lens 2 and the high refractive index member 4 may be surrounded by a lens holder 70 for sealing or fixing these elements.

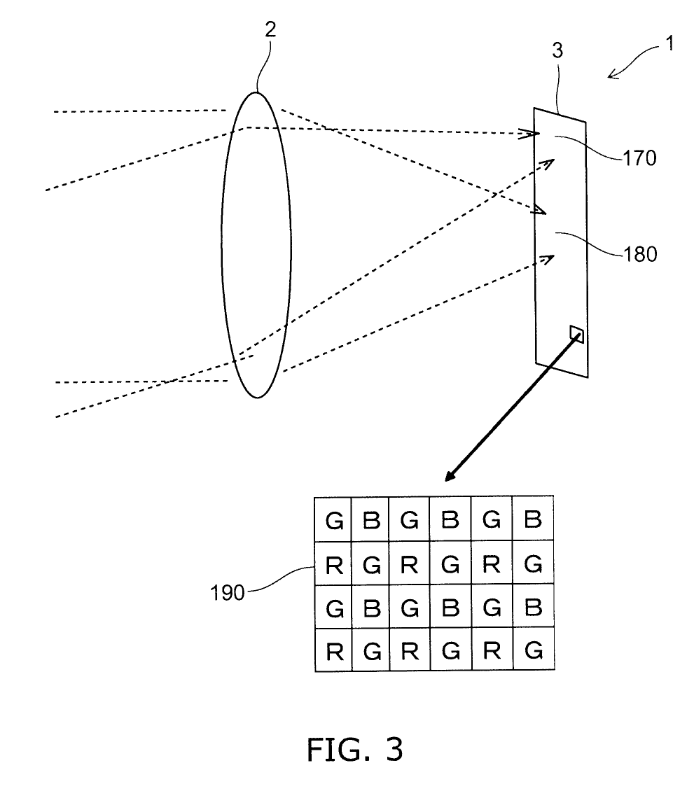

Next, the effect of this embodiment is described with reference to FIGS. 3 to 5B.

First, the background of the invention is additionally described with reference to FIG. 3.

FIG. 3 includes a schematic perspective view showing an imaging device 1 composed of an imaging lens 2 and an arrayed light receiving element 3 and a schematic view showing an enlarged portion 190 of the arrayed light receiving element 3. Here, R, G, and B in the enlarged portion 190 of the arrayed light receiving element represent the position of elements including visible filters of red, green, and blue colors, respectively.

In the imaging device 1, when light is incident on the arrayed light receiving element 3 from the imaging lens 2, the component of perpendicular incident light is intense in the center portion 180 of the arrayed light receiving element, whereas the component of oblique incident light is intense in the peripheral portion 170 of the arrayed light receiving element. The oblique incident light may impinge on a wiring and the like in the element and fail to reach the light receiving portion in the element, decreasing the light receiving sensitivity in the peripheral portion. Hence, in the two-dimensionally arrayed element, the light receiving sensitivity is high in the center portion, but low in the peripheral portion, causing a sensitivity difference (shading) therebetween. Furthermore, light may be incident on the light receiving portion of the adjacent pixel and cause color mottling.

Here, the oblique incident light can be caused to reach the light receiving portion 3a of the element using the focusing unit 3c. However, the progress of downscaling of the element imposes limitations on using only the focusing unit 3c to cause light to reach the light receiving portion 3a.

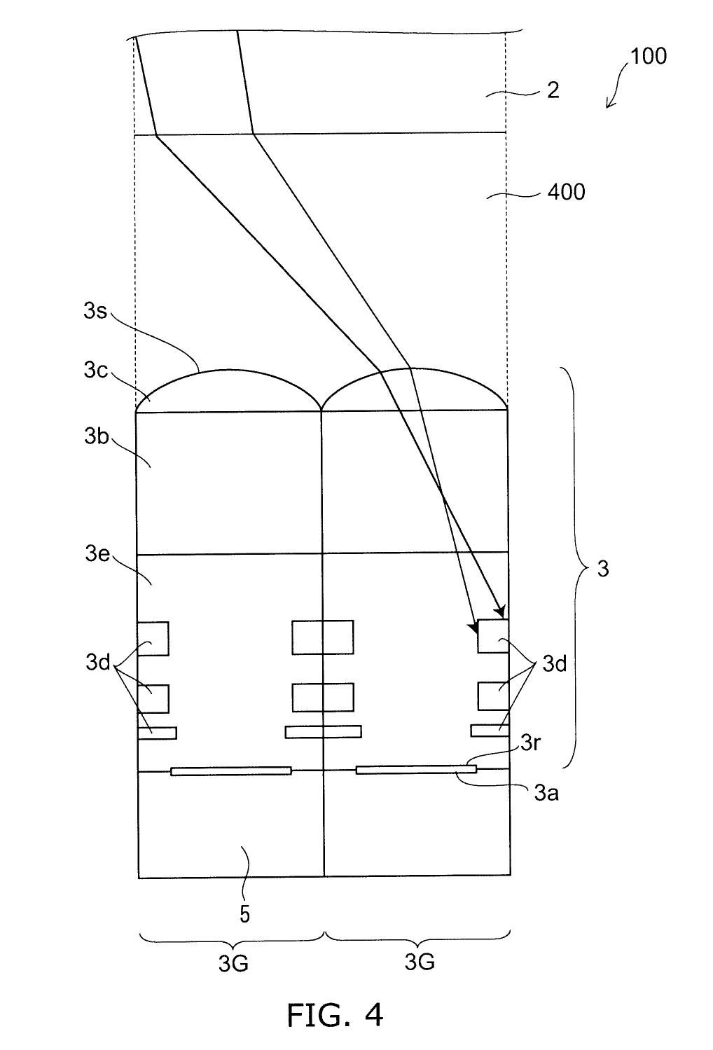

FIG. 4 is a schematic cross-sectional view enlarging a neighborhood of a light receiving element of an imaging device 100 according to a comparative example contrasted with this embodiment.

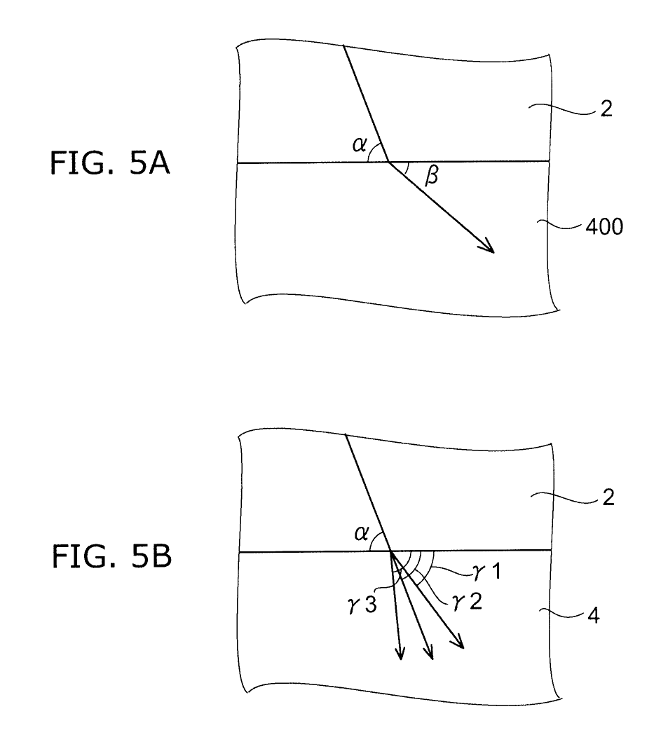

FIGS. 5A and 5B are schematic views showing the traveling direction of light on the emitting side of the imaging lens 2, where FIG. 5A shows the traveling direction of light in the comparative example, and FIG. 5B shows the traveling direction of light in this embodiment.

As shown in FIG. 4, the imaging device 100 according to the comparative example does not include the high refractive index member 4. Air 400 exists between the imaging lens 2 and the light receiving element 3. Hence, as shown in FIG. 5A, light transmitted through the imaging lens 2 travels in a relatively oblique direction. Thus, as shown in FIG. 4, in the light receiving element 3, the light impinges on a wiring 3d and the like, and is more likely to fail to reach the light receiving portion 3a.

In contrast, as shown in FIG. 2, in the imaging device 1A according to this embodiment, light transmitted through the imaging lens 2 passes through the high refractive index member 4. Hence, as shown in FIG. 5B, the light transmitted through the imaging lens 2 travels in a relatively downward direction, that is, toward the light receiving portion 3a. If the light is emitted from the imaging lens 2 at angle a from the interface, then in the comparative example, as shown in FIG. 5A, the light travels in the direction of angle β from the interface, whereas in this embodiment, as shown in FIG. 5B, the light travels in the direction of angles γ1, γ2, γ3 and the like (hereinafter generically referred to as “angle γ”) larger than β. The angle γ depends on the refractive index of the high refractive index member 4, and with the increase of the refractive index, γ increases, that is, the light tends to travel toward the light receiving portion 3a. Subsequently, the light transmitted through the high refractive index member 4 is sensed by the light receiving element 3 (light receiving portion 3a) in contact with the high refractive index member 4.

Thus, in this embodiment, light is more likely to be incident on the light receiving portion 3a than in the comparative example. Hence, even if the pitch spacing of the light receiving element 3 is narrow, high light receiving ratio is achieved for the light obliquely incident on the imaging lens 2. That is, this embodiment can provide an imaging device having high light receiving efficiency and being capable of resolving fine pixels. Thus, the resolution is enhanced. Furthermore, even if the aperture is reduced, for instance in the dark, that is, even if the imaging lens has a small F-number, the oblique incident light can be decreased, and the light receiving efficiency can be increased. Thus, the sensitivity is enhanced.

This embodiment is suitably applicable to CMOS (complementary metal oxide semiconductor) image sensors, CCD (charge coupled device) image sensors and the like. With the progress of anti-shading techniques responding to the downscaling of the arrayed light receiving element, this embodiment can be applied to cell phone cameras with a larger number of pixels. Furthermore, in a compact digital camera, this embodiment can contribute to downsizing compatible with increased image quality. This embodiment can illustratively provide an imaging device having a pixel size of e.g. several μm or less.

### EXAMPLE 2

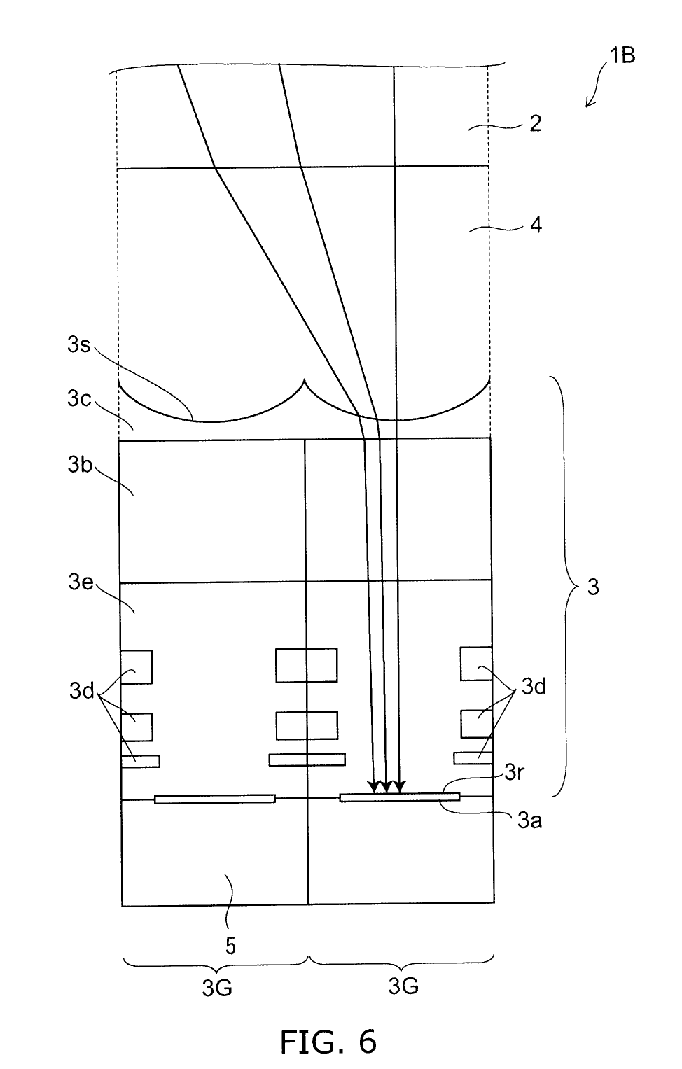

Next, another example (Example 2) of the imaging device according to this embodiment is described with reference to FIG. 6.

FIG. 6 is a schematic cross-sectional view illustrating an imaging device 1B according to Example 2. Like FIG. 2, FIG. 6 shows a neighborhood of the light receiving element 3.

As shown in FIG. 6, as in Example 1, the light receiving element 3 includes a plurality of pixels 3G, and the pixel 3G includes a focusing unit 3c. Here, the focusing unit 3c has a lower refractive index than the high refractive index member 4 and has a concave surface on the incident side. The focusing unit 3c can be made of a material such as oxides and nitrides of metals and silicon, or resin, and suitably selected so as to have a lower refractive index than the high refractive index member 4.

Also in Example 2, because of the presence of the high refractive index member 4, the incident light can be appropriately guided toward the light receiving portion 3a by the aforementioned mechanism. Furthermore, the focusing unit 3c has a lower refractive index than the high refractive index member 4 and has a concave shape. Hence, as in Example 1, light is refracted downward in the focusing unit 3c and guided toward the light receiving portion 3a.

Thus, Example 2 can also provide an imaging device having high light receiving ratio for oblique incident light even for narrow pitch spacing, and being superior in sensitivity and resolution.

### EXAMPLE 3

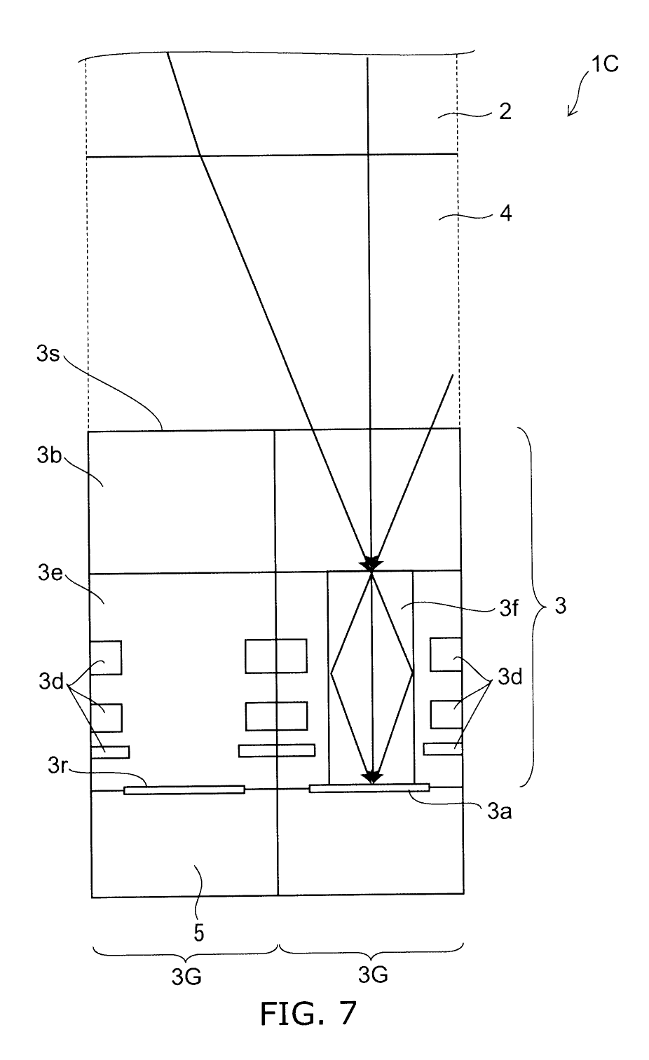

Next, still another example (Example 3) of the imaging device according to this embodiment is described with reference to FIG. 7.

FIG. 7 is a schematic cross-sectional view illustrating an imaging device 1C according to Example 3. Like FIG. 2, FIG. 7 shows a neighborhood of the light receiving element 3.

As shown in FIG. 7, in Example 3, at least in part between the incident surface 3s and the major surface on which the light receiving portion 3a is provided, the light receiving element 3 includes a first region (waveguide 3e) having a relatively high refractive index, and a second region (insulating layer 3f) having a relatively low refractive index and surrounding at least part of the outer periphery of the first region above the major surface. The waveguide 3f has the function of guiding light toward the light receiving portion 3a.

Also in Example 3, because of the presence of the high refractive index member 4, the incident light can be appropriately guided toward the light receiving portion 3a by the aforementioned mechanism. Furthermore, the waveguide 3f further guides the incident light toward the light receiving portion 3a. More specifically, because of the waveguide 3f having a higher refractive index than the insulating layer 3e, light is more likely to be totally reflected at the interface between the insulating layer 3e and the waveguide 3f, and tends to be confined in the waveguide 3f. Thus, the light is more likely to travel in the waveguide 3f. Hence, the incident light is favorably guided to the light receiving portion 3a.

Thus, Example 3 can also provide an imaging device having high light receiving ratio for oblique incident light even for narrow pitch spacing, and being superior in sensitivity and resolution.

### Method for Manufacturing an Imaging Device

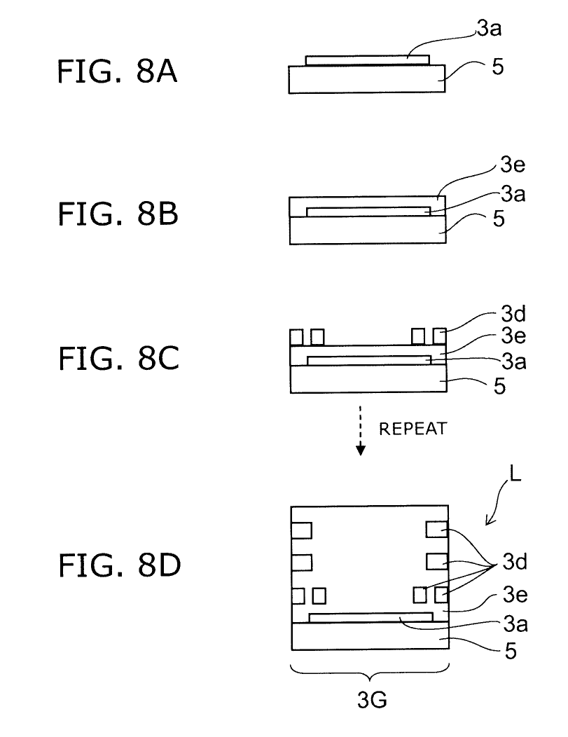

Next, a method for manufacturing an imaging device according to this embodiment is described with reference to FIGS. 8A to 17C.

FIGS. 8A to 17C are schematic process cross-sectional views illustrating the method for manufacturing an imaging device according to this embodiment.

The method according to this embodiment includes the processes of forming a light receiving element 3 including a light receiving portion 3a for sensing light, forming a high refractive index member 4 having a higher refractive index than air on the light incident side of the light receiving element 3 so as to be in contact with the light receiving element 3, and forming an imaging lens 2 on the light incident side of the high refractive index member 4 so as to be in contact with the high refractive index member 4. A detailed description is given in the following.

First, as shown in FIG. 8A, a light receiving portion 3a, such as a photodiode, is formed on a substrate 5 illustratively made of Si. The light receiving portion 3a can be patterned illustratively by etching using a mask so that adjacent pixels are spaced from each other. Subsequently, as shown in FIG. 8B, an insulating layer 3e illustratively made of metal oxide is formed on the substrate 5 and the light receiving portion 3a. Subsequently, as shown in FIG. 8C, a wiring 3d is formed on the insulating layer 3e. The wiring 3d can be formed by uniformly forming a material layer of the wiring 3d and then patterning it by etching. Subsequently, this process is repeated to complete a multilayer logic portion L shown in FIG. 8D. Here, the wirings 3d can be provided in the peripheral portion of the pixel 3G so that only the insulating layer 3e is disposed in the center portion of the pixel 3G. This makes the incident light more likely to appropriately reach the light receiving portion 3a.

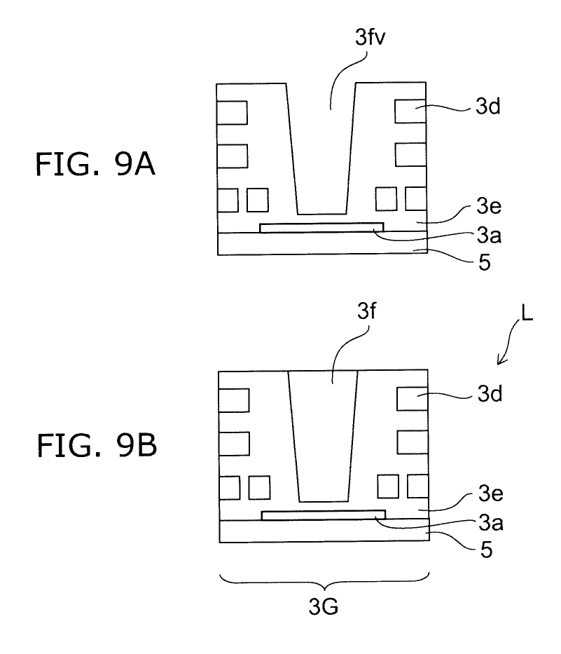

In the case of fabricating an imaging device including a waveguide 3f, as shown in FIG. 9A, a void 3fv is formed in the insulating layer 3e illustratively by RIE (reactive ion etching). Subsequently, as shown in FIG. 9B, the material of the waveguide 3f is buried in the void 3fv illustratively by CVD (chemical vapor deposition) or coating. Thus, the waveguide 3f is formed.

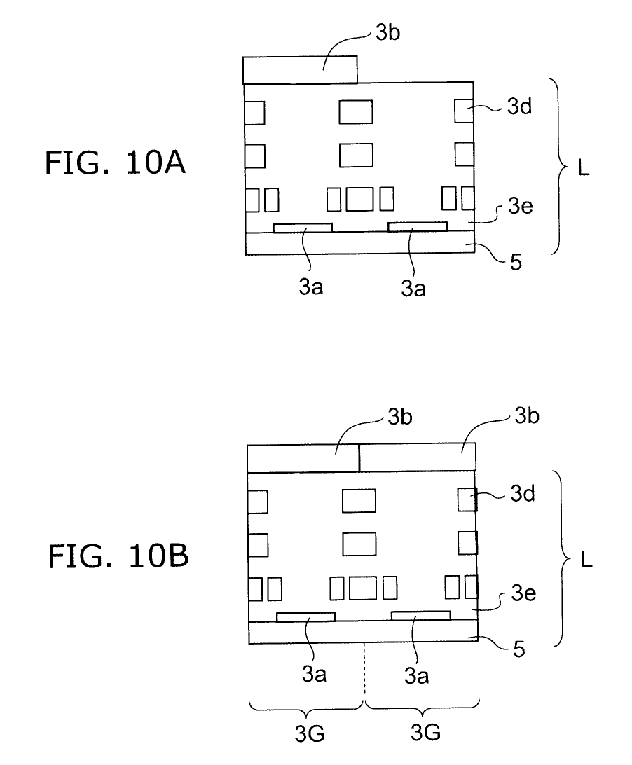

Next, a description is given with reference to FIGS. 10A and 10B. Although a single pixel 3G has been shown in FIGS. 8A to 8D and FIGS. 9A and 9B, two pixels 3G are shown in FIGS. 10A and 10B and the subsequent figures.

As shown in FIGS. 10A and 10B, a color filter 3b of RGB (red, green, blue) and the like is formed on the logic portion L. The color filter 3b can be patterned by, for instance, forming a photosensitive color resist film and then exposing it to light. Alternatively, if the material used is not photosensitive, it can be patterned by etching. To form the color filters 3b of RGB and the like, this process is performed for each color.

Next, a focusing unit 3c is formed using a “transfer” process.

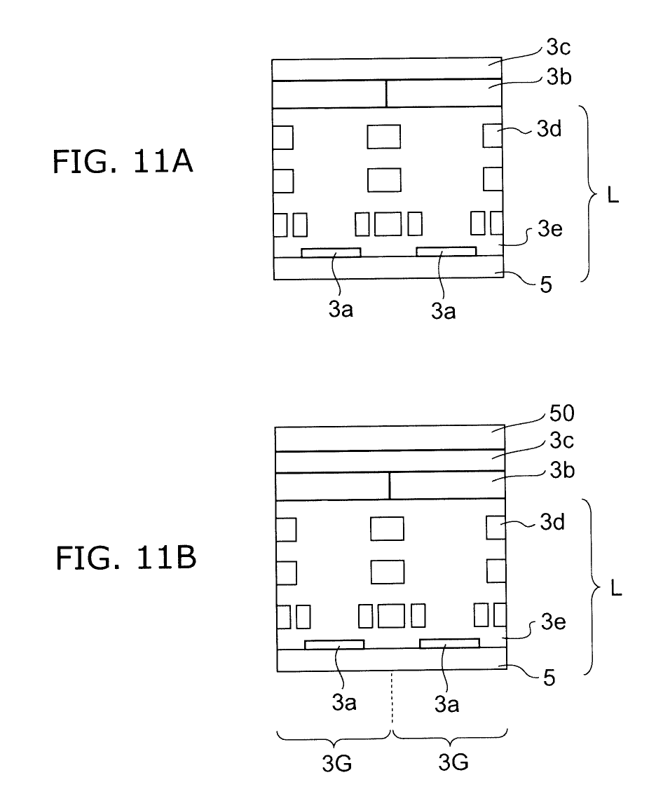

First, as shown in FIG. 11A, a material layer of the focusing unit 3c such as a microlens is formed on the color filter 3b. Subsequently, as shown in FIG. 11B, a photosensitive resist film 50 is formed.

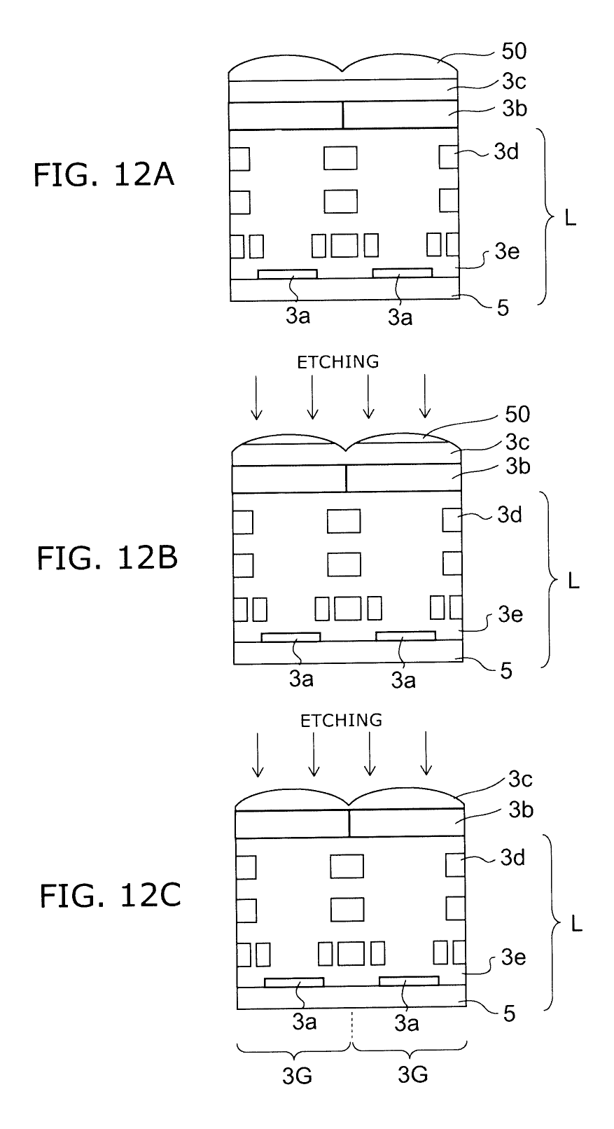

Subsequently, as shown in FIG. 12A, light exposure is performed using a grating mask, not shown. The grating mask can be a mask having nonuniform transmittance, which is relatively high in the peripheral portion of the pixel 3G. In this case, as shown in FIG. 12A, the incident side of the resist film 50 has a convex shape generally at the center of the pixel 3G. Subsequently, as shown in FIG. 12B, RIE or other etching is performed. Thus, as shown in FIG. 12C, the convex shape of the resist film 50 is transferred to the layer of the focusing unit 3c. Consequently, the focusing unit 3c or microlens, having a convex shape on the incident side is formed.

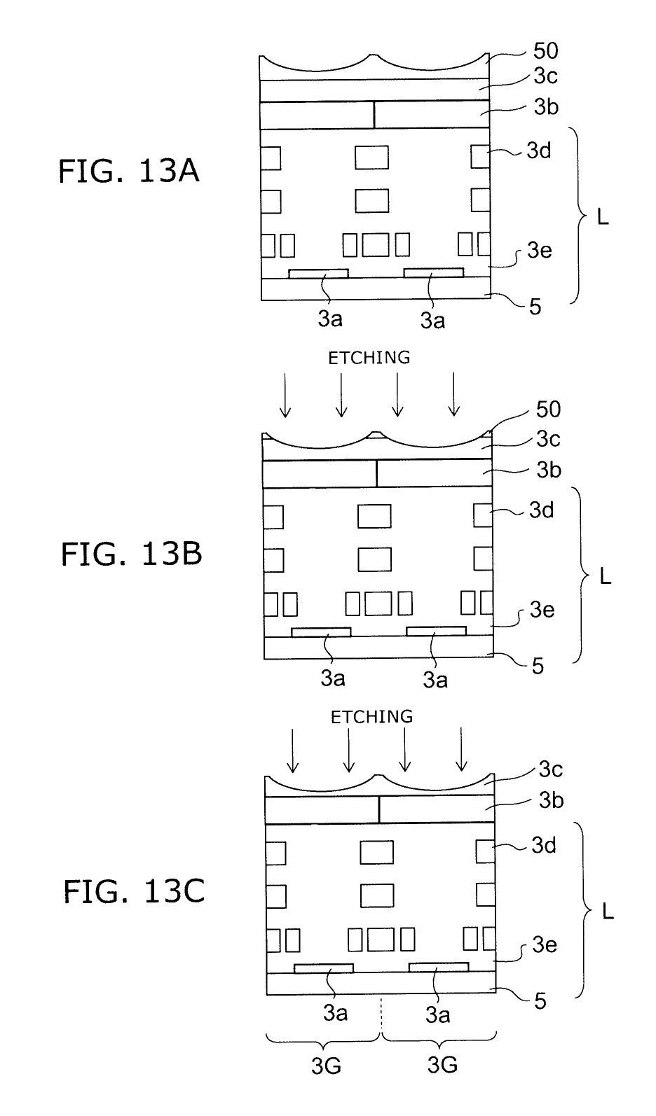

Alternatively, to form a focusing unit 3c or microlens, having a concave shape on the incident side generally at the center of the pixel 3G, as shown in FIGS. 13A to 13C, light exposure is performed using a grating mask whose transmittance is relatively high in the center portion of the pixel 3G, and etching can be performed in the manner described above with reference to FIGS. 12A to 12C. Thus, the concave shape of the resist film 50 is transferred to the layer of the focusing unit 3c.

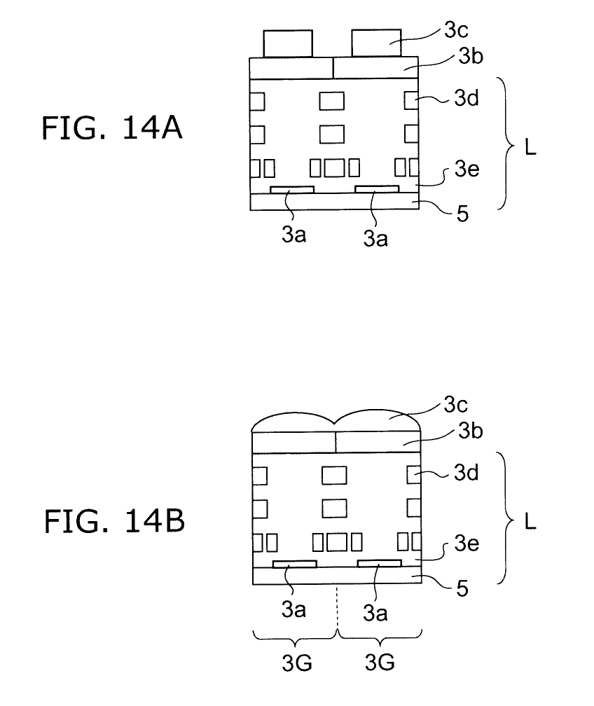

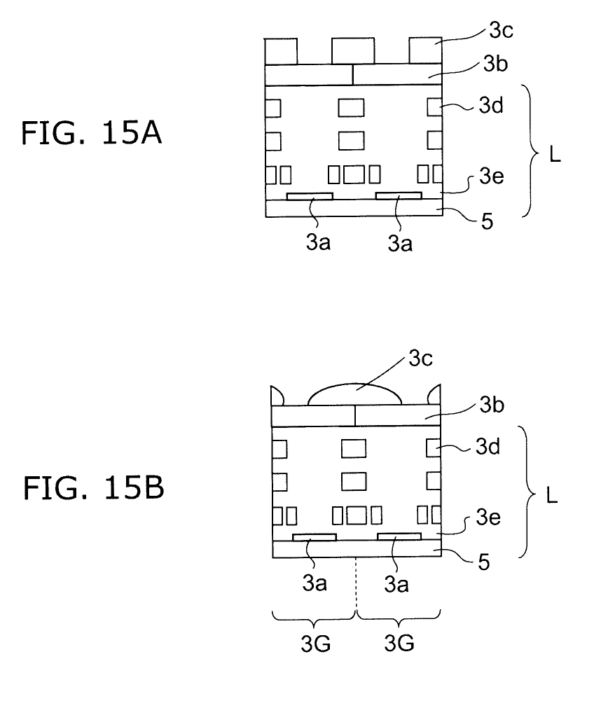

Thus, the light receiving element 3 is fabricated. As an alternative method for forming the focusing unit 3c, a method based on thermal melting can be used. This is described with reference to FIGS. 14A and 14B and FIGS. 15A and 15B.

First, as shown in FIG. 14A, a material layer of the focusing unit 3c, illustratively made of a photosensitive resist material, is formed on the color filter 3b, and exposed to light using a mask. Thus, the material layer of the focusing unit 3c is selectively formed on the light receiving element 3. The material layer of the focusing unit 3c can be selectively formed in the center portion of the pixel 3G. Subsequently, as shown in FIG. 14B, the material layer of the focusing unit 3c is thermally melted. Thus, the focusing unit 3c having a convex shape on the incident side generally at the center of the pixel 3G is formed.

Alternatively, to form a focusing unit 3c having a concave shape on the incident side generally at the center of the pixel 3G, as shown in FIGS. 15A and 15B, the material layer of the focusing unit 3c can be selectively formed so as to extend over the adjacent pixels 3G. Subsequently, the material layer of the focusing unit 3c can be thermally melted to form the focusing unit 3c, which is relatively thick in the peripheral portion of the pixel 3G. That is, the focusing unit 3c having a concave shape on the incident side generally at the center of the pixel 3G is formed.

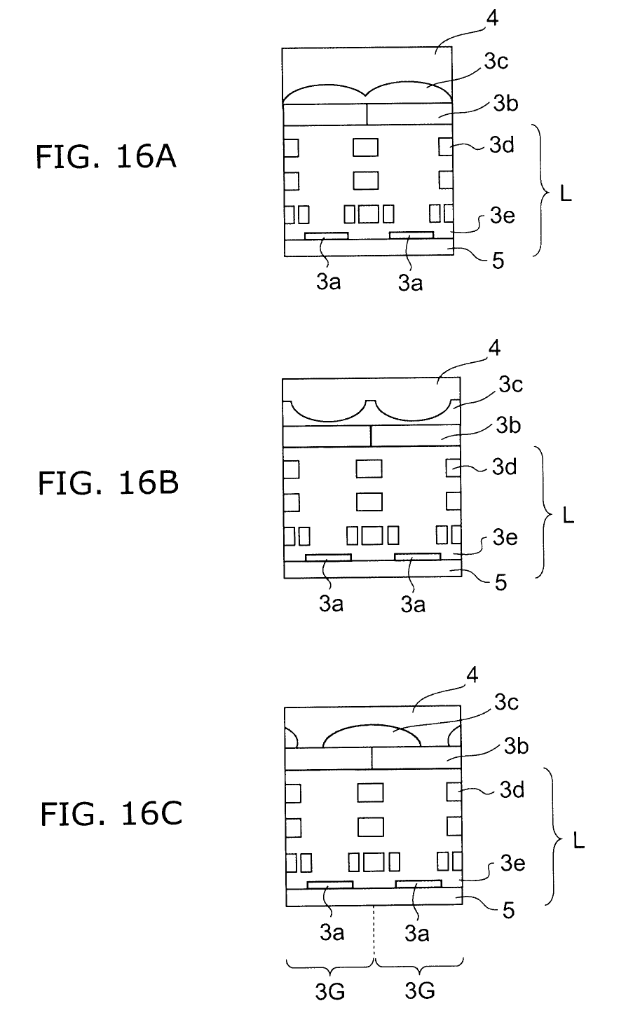

Next, as shown in FIGS. 16A to 16C, a high refractive index member 4 is formed on the focusing unit 3c illustratively by coating. FIG. 16A is a process cross-sectional view for the convex focusing unit 3c, and FIGS. 16B and 16C are process cross-sectional views for the concave focusing unit 3c.

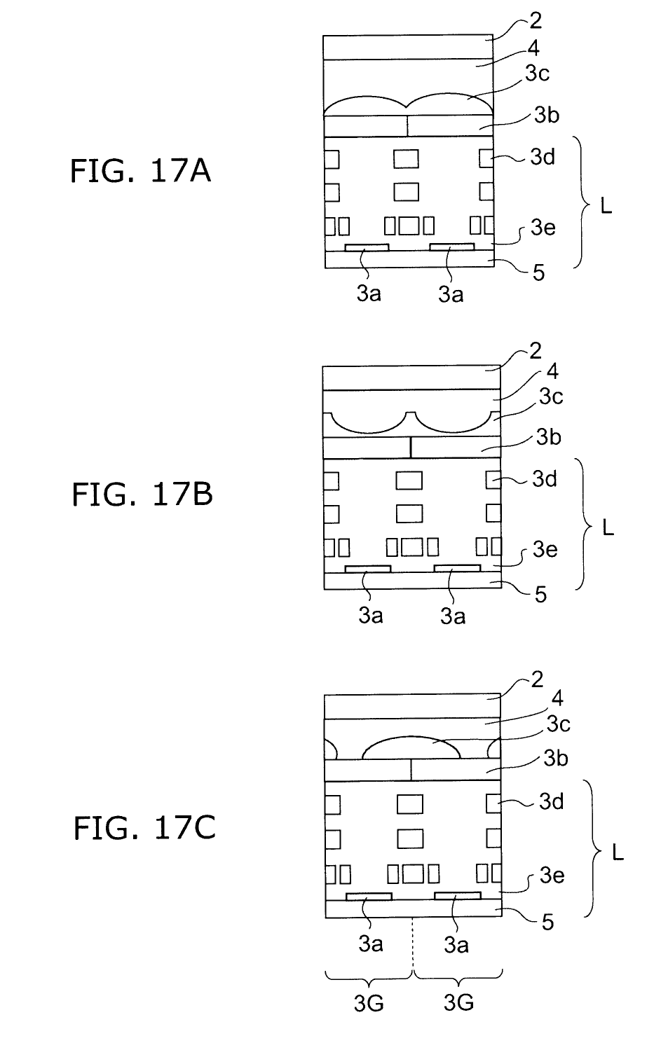

Next, as shown in FIGS. 17A to 17C, an imaging lens 2 is formed on the high refractive index member 4. FIG. 17A is a process cross-sectional view for the convex focusing unit 3c, and FIGS. 17B and 17C are process cross-sectional views for the concave focusing unit 3c.

Thus, the imaging device according to this embodiment is fabricated.

The embodiment of the invention has been described with reference to examples. However, the invention is not limited to these examples. That is, those skilled in the art can suitably modify these examples, and such modifications are also encompassed within the scope of the invention as long as they fall within the spirit of the invention. For instance, the components of the above examples and the layout, material, condition, shape, size and the like thereof are not limited to those illustrated, but can be suitably modified.

Furthermore, the components of the above embodiment can be combined with each other as long as technically feasible, and such combinations are also encompassed within the scope of the invention as long as they fall within the spirit of the invention.

1. An imaging device comprising:
an imaging lens;
a light receiving element including a light receiving portion configured to sense light transmitted through the imaging lens; and
a high refractive index member packed between the imaging lens and the light receiving element and having a higher refractive index than air.

2. The device according to claim 1, wherein
the light receiving element includes a plurality of pixels,
the pixels include a focusing unit configured to focus the light transmitted through the imaging lens, and
the focusing unit has a higher refractive index than the high refractive index member and has a convex surface on an incident side of the light.

3. The device according to claim 1, wherein
the light receiving element includes a plurality of pixels,
the pixels include a focusing unit configured to focus the light transmitted through the imaging lens, and
the focusing unit has a lower refractive index than the high refractive index member and has a concave surface on an incident side of the light.

4. The device according to claim 1, wherein the high refractive index member has any one of vapor, liquid, and solid state at ordinary temperatures and pressures.

5. The device according to claim 1, wherein
the high refractive index member is made of at least one of water, ethyl alcohol, benzene, polyethylene, polystyrene, and silicone, or
the high refractive index member is made of a resin dispersed with a metal oxide nano-sized particle containing at least one of zirconium (Zr), titanium (Ti), tin (Sn), cerium (Ce), tantalum (Ta), niobium (Nb), and zinc (Zn), or
the high refractive index member is made of a nitride.

6. The device according to claim 1, further comprising:
a filter configured to block infrared radiation and provided on an incident side of the light of the light receiving element.

7. The device according to claim 1, wherein the light receiving element includes a first region and a second region at least in part between an incident surface of the light and a major surface, the light receiving portion being provided on the major surface,
the first region having a relatively high refractive index,
and the second region having a relatively low refractive index and surrounding at least part of an outer periphery of the first region above the major surface.

8. The device according to claim 7, wherein the first region functions as a waveguide configured to guide the light to the light receiving portion.

9. A method for manufacturing an imaging device, comprising:
forming a light receiving element including a light receiving portion configured to sense light;
forming a high refractive index member having a higher refractive index than air on an incident side of the light of the light receiving element so as to be in contact with the light receiving element; and
forming an imaging lens on an incident side of the light of the high refractive index member so as to be in contact with the high refractive index member.

10. An imaging method comprising:
transmitting light through an imaging lens;
transmitting the light transmitted through the imaging lens through a high refractive index member being in contact with the imaging lens and having a higher refractive index than air; and
being sensed the light transmitted through the high refractive index member by a light receiving element being in contact with the high refractive index member.
